(19) United States
(12) Patent Application Publication
(10) Pub. No.: US 2002/0144840 A1
(43) Pub. Date: Oct. 10, 2002

(54) Leadframe package with dummy chip

(76) Inventors: Johnson C.H. Tzu, Taipei (TW); Jerry Y.J. Wu, Taoyuan (TW); Jung Yu Lee, Hsinchu (TW)

Correspondence Address: Chun M. Ng, BLAKELY, SOKOLOFF, TAYLOR & ZAFMAN LLP, Seventh Floor, 12400 Wilshire Boulevard, Los Angeles, CA, 90025-1026, US

(21) Appl. No.: 09/829,506

(22) Filed: Apr. 9, 2001

(51) Int. Cl. H05K 1/16

(52) U.S. Cl. 174/260

(57) ABSTRACT

The lead frame package with dummy chip comprising a lead frame with a plurality of first leads, molding compound, a dummy chip and a die. Wherein the molding compound encapsulates the die and the dummy chip, the dummy chip is arranged on a lower portion of the molding compound. The die is stacked on an upper surface of the dummy chip by using an adhesive material. A plurality of bonding wires are connected between the die and an end of the plurality of leads over the dummy chip.

### FIELD OF THE INVENTION

The present invention relates to a semiconductor package, and more specifically, to a lead frame package with a dummy chip.

### BACKGROUND OF THE INVENTION

Integrated circuits industry and fabrication involve the formation of semiconductor wafers, integrated circuits and chip package. With the advent of Ultra Large Scale Integrated (ULSI) circuits technologies, it has been a trend to scale down the geometry dimension of semiconductor devices and increase the density of semiconductor devices per unit area of silicon wafer. Thus, the sizes of devices have gotten smaller and smaller such that the area available for a single device has become very small. Further, the manufacturers of the devices are striving to reduce the sizes while simultaneously increasing their speed. Developments in interconnect and packing have been quite modest in comparison. The renewed interest in high density hybrid is driven by the requirement to handle large numbers of IC interconnections, the increasing clock rate of digital systems and the desire to pack greater functionality into smaller spaces. Therefore, the number of a package's leads becomes more and more.

Therefore, an important consideration in making small, high speed and high-density devices is providing packages capable of the spreading heat generated by the devices. A further problem confronting the technology is the relentless need for more I/O per chip. Those issues lead to the requirement of more power for devices and the reduction of impedance of inductance. A conventional lead frame package with die paddle to receive the die does not have good performance in removing the heat generated by the devices, and it also has a limitation to increase the number of the package's leads. What is need is to provide a novel lead frame structure.

U.S. Pat. No. 5,789,816 disclosed a lead frame structure, entitled “Multiple-chip integrated circuit package including a dummy chip”. The inventor is Mr. Wu and assigned to assignee: United Microelectronics Corporation. The multiple-chip IC package is used to contain a number of chips therein. The multiple-chip IC package includes a leadframe, at least one IC chip mounted on the first area of the leadframe, and at least one dummy chip is mounted on the second area of the leadframe. On the dummy chip, there is provided with a plurality of bonding pads which serve as intermediate bonding pads between the chips and the pins on the lead frame so that any two connecting points are connected by a number of straight wires via the dummy chip. This allows the wire bonding process to be much easier to conduct.

### SUMMARY OF THE INVENTION

The object of the present invention is to provide a lead frame package with a dummy package.

The lead frame package with dummy chip comprising a lead frame with a plurality of first leads, molding compound, a dummy chip and a die. Wherein the molding compound encapsulates the die and the dummy chip, the dummy chip is arranged on a lower portion of the molding compound. The die is stacked on an upper surface of the dummy chip by using an adhesive material. A plurality of bonding wires are connected between the die and an end of the plurality of leads over the dummy chip.

The dummy chip is formed of silicon and refers to a substrate without IC formed therein.

### BRIEF DESCRIPTION OF THE DRAWINGS

FIG. 1 is the cross section view of a structure according to the present invention.

FIG. 2 is the top view of a structure of the first embodiment according to the present invention.

FIG. 3 is the top view of a structure of the first embodiment according to the present invention.

### DETAILED DESCRIPTION OF THE PREFERRED EMBODIMENT

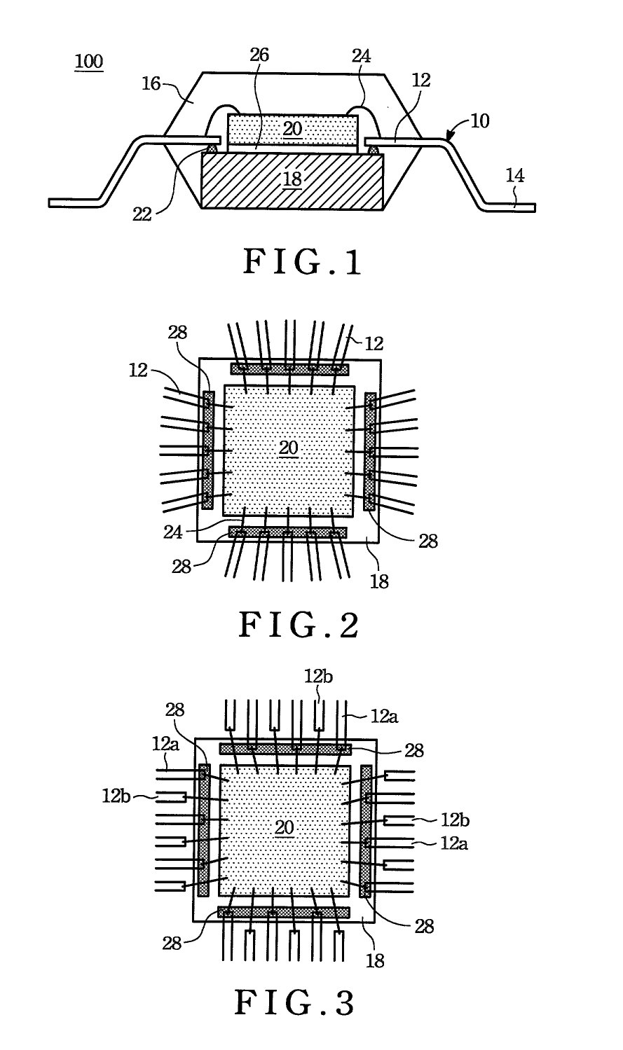

The present invention discloses a novel structure of a package 100. FIG. 1 is a cross section view of an embodiment of the present invention and FIG. 2 and FIG. 3 are the top view of the present invention.

As shown therein, the package 100 includes a lead frame 10 without conventional die paddle to receive the die. The lead frame 10 has inner leads 12 and outer leads 14. In the present invention, molding material (compound) 16 encapsulates a die 20 and a dummy chip 18 configured as stacked structure. The dummy chip 18 is arranged on the lower portion of the molding compound 16 and the lower surface of the dummy chip 18 may be exposed. The dummy chip refers to the substrate without IC formed therein. Preferably, the material for the dummy chip 18 includes but not limited to silicon. The dummy chip 18 is fixed by the tapes 28 adhesive on the inner leads 12 of the lead frame 10.The die 20 is stacked on the upper surface of the dummy chip 18 by using adhesive material 26. The benefit of the present invention is that the metal sink is omitted, which may reduce the manufacture cost. Further, die paddle is not necessary for the present invention. The dummy chip 18 is exposed by the molding compound, which can improve the efficiency of spreading heat. General speaking, the die 20 generates a lot of heat during operation. The dummy chip 18 promotes thermal generated by the die 20 away from the die 20.

A plurality of bonding wires 24 are electrically connected between the die and the inner leads 12. The bonding wires 24 are used to provide electrical conductive path for signal transfer. The bonding wires 24 can be selected from gold, copper or conductive metal or alloy.

Still turning to FIG. 2, a tap 28 is used to fix the inner leads 12. Another embodiment is illustrated in FIG. 3, the example includes the dummy chip 18 fixed by a few inner leads 12a adheive tapes 18. Alternate distribution of the inner leads 12a and 12b can improve the yield, especially high-density wire bonding. Further inner leads 12b are set outside the dummy chip 18, the die is connected to the inner leads 12b by means of bonding wires 24.

The present invention provides the dummy chip 18 to improve the thermal dispersion and reduce the cost.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure. Thus, while the preferred embodiment of the invention has been illustrated and described, it will be appreciated that various changes can be made therein without departing from the spirit and scope of the invention.

I claim:

1. A lead frame package with dummy chip comprising:
a lead frame with a plurality of first leads;
a molding compound;
a dummy chip and a die, wherein said molding compound encapsulates said die and said dummy chip, said dummy chip being arranged on a lower portion of said molding compound, said die being stacked on an upper surface of said dummy chip by using an adhesive material; and
tapes connected between said die and an end of said plurality of first leads over said dummy chip.

2. The package of claim 1, wherein said dummy chip is formed of silicon.

3. The package of claim 1, wherein said dummy chip refers to a substrate without IC formed therein.

4. The package of claim 1, wherein said dummy chip is exposed by said molding compound, which can improve the efficiency of spreading heat.

5. The package of claim 1, further comprises a tape to fix said plurality of first leads.

6. The package of claim 1, wherein said lead frame further comprises a plurality of second leads outside said dummy chip.

7. The package of claim 1, wherein said die is attached on said dummy chip by adhesive material.
